(19) United States
(12) Patent Application Publication
(10) Pub. No.: US 2025/0294847 A1
(43) Pub. Date: Sep. 18, 2025

(54) DIRECT BACKSIDE CONTACT INTEGRATION WITH THICK SILICON LAYER

(71) Applicant: International Business Machines Corporation, Armonk, NY (US)

(72) Inventors: Richard C. Johnson, Selkirk, NY (US); Ruilong Xie, Niskayuna, NY (US); Alex Hubbard, Rensselaer, NY (US); Nikhil Jain, Apple Valley, MN (US); Vinay Pai, Voorheesville, NY (US); Cody J. Murray, Burnt Hills, NY (US)

(21) Appl. No.: 18/607,881

(22) Filed: Mar. 18, 2024

(51) Int. Cl. H01L 29/417; H01L 23/528; H01L 29/40

(52) U.S. Cl. CPC H10D 64/254; H01L 23/5286; H10D 64/01

(57) ABSTRACT

Embodiments of the present disclosure are directed to processing methods and resulting structures for providing direct backside contact integrations with thick silicon layers to enable passive device and tight active region of NFET-to-active region of PFET (N2P) spacing. In a non-limiting embodiment, a method includes forming a backside contact electrically coupled to a first source or drain (S/D) region. The backside contact includes an upper portion and a lower portion. The lower portion has a larger critical dimension than the upper portion. A frontside contact is electrically coupled to a second S/D region and a backside contact dielectric liner conformally wraps around the upper portion and the lower portion of the backside contact.

### BACKGROUND

The present disclosure generally relates to fabrication methods and resulting structures for semiconductor devices, and more specifically, to processing methods and resulting structures for direct backside contact (DBC) integration with thick silicon layers to enable passive device and tight active region of NFET to active region of PFET (N2P) spacing.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively PPA, is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

A key component of the BEOL structure is the power delivery network (PDN). The PDN of an integrated circuit is defined by the conductors and vias connected to the power supply (VDD) and ground (VSS) terminals of the chip. The PDN is responsible for delivering power to the individual devices in the front end. The integration of the PDN in the BEOL has become particularly challenging as device densities continue to scale. Backside power delivery is one known solution to this problem, and involves moving some (or most, or all) layers of the PDN from the front side of the integrated circuit to the back side. In a backside-style architecture, the repositioned layers are not formed on top of the FEOL, but are instead formed on the opposite side of the chip (i.e., on the backside of the semiconductor substrate onto which the active devices have been built).

### SUMMARY

Embodiments of the disclosure are directed to a method for providing direct backside contact integrations with thick silicon layers to enable passive device and tight active region of NFET-to-active region of PFET (N2P) spacing. A non-limiting example of the method includes forming a backside contact electrically coupled to a first source or drain (S/D) region. The backside contact includes an upper portion and a lower portion. The lower portion has a larger critical dimension than the upper portion. A frontside contact is electrically coupled to a second S/D region and a backside contact dielectric liner conformally wraps around the upper portion and the lower portion of the backside contact.

Embodiments of the disclosure are directed to a semiconductor structure. A non-limiting example of the semiconductor structure includes a backside contact electrically coupled to a first S/D region. The backside contact includes an upper portion and a lower portion, the lower portion having a larger critical dimension than the upper portion. The structure further includes a frontside contact electrically coupled to a second S/D region and a backside contact dielectric liner that conformally wraps around the upper portion and the lower portion of the backside contact.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1A is a top-down reference view of a first region of a semiconductor wafer after an initial set of processing operations according to one or more embodiments;

FIG. 1B is a top-down reference view of a second region of the semiconductor wafer after the initial set of processing operations according to one or more embodiments;

FIGS. 2A, 2B, and 2C depict cross-sectional views of the semiconductor wafer of FIGS. 1A and 1B taken along the lines X1, Y, and X2, respectively, after a processing operation according to one or more embodiments;

FIGS. 3A, 3B, and 3C depict cross-sectional views of the semiconductor wafer of FIGS. 1A and 1B taken along the lines X1, Y, and X2, respectively, after a processing operation according to one or more embodiments;

FIGS. 4A, 4B, and 4C depict cross-sectional views of the semiconductor wafer of FIGS. 1A and 1B taken along the lines X1, Y, and X2, respectively, after a processing operation according to one or more embodiments;

FIGS. 5A, 5B, and 5C depict cross-sectional views of the semiconductor wafer of FIGS. 1A and 1B taken along the lines X1, Y, and X2, respectively, after a processing operation according to one or more embodiments;

FIGS. 6A, 6B, and 6C depict cross-sectional views of the semiconductor wafer of FIGS. 1A and 1B taken along the lines X1, Y, and X2, respectively, after a processing operation according to one or more embodiments;

FIGS. 7A, 7B, and 7C depict cross-sectional views of the semiconductor wafer of FIGS. 1A and 1B taken along the lines X1, Y, and X2, respectively, after a processing operation according to one or more embodiments;

FIGS. 8A, 8B, and 8C depict cross-sectional views of the semiconductor wafer of FIGS. 1A and 1B taken along the lines X1, Y, and X2, respectively, after a processing operation according to one or more embodiments;

FIGS. 9A, 9B, and 9C depict cross-sectional views of the semiconductor wafer of FIGS. 1A and 1B taken along the lines X1, Y, and X2, respectively, after a processing operation according to one or more embodiments;

FIGS. 10A, 10B, and 10C depict cross-sectional views of the semiconductor wafer of FIGS. 1A and 1B taken along the lines X1, Y, and X2, respectively, after a processing operation according to one or more embodiments;

FIGS. 11A, 11B, and 11C depict cross-sectional views of the semiconductor wafer of FIGS. 1A and 1B taken along the lines X1, Y, and X2, respectively, after a processing operation according to one or more embodiments;

FIGS. 12A, 12B, and 12C depict cross-sectional views of the semiconductor wafer of FIGS. 1A and 1B taken along the lines X1, Y, and X2, respectively, after a processing operation according to one or more embodiments;

FIGS. 13A, 13B, and 13C depict cross-sectional views of the semiconductor wafer of FIGS. 1A and 1B taken along the lines X1, Y, and X2, respectively, after a processing operation according to one or more embodiments;

FIGS. 14A, 14B, and 14C depict cross-sectional views of the semiconductor wafer of FIGS. 1A and 1B taken along the lines X1, Y, and X2, respectively, after a processing operation according to one or more embodiments;

FIGS. 15A, 15B, and 15C depict cross-sectional views of the semiconductor wafer of FIGS. 1A and 1B taken along the lines X1, Y, and X2, respectively, after a processing operation according to one or more embodiments; and

FIG. 16 depicts a flow diagram illustrating a method according to one or more embodiments.

The diagrams depicted herein are illustrative. There can be many variations to the diagram or the operations described therein without departing from the spirit of the disclosure. For instance, the actions can be performed in a differing order or actions can be added, deleted or modified.

In the accompanying figures and following detailed description of the described embodiments of the disclosure, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the disclosure are described in connection with a particular transistor architecture, embodiments of the disclosure are not limited to the particular transistor architectures or materials described in this specification. Rather, embodiments of the present disclosure are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

As discussed previously, a key component of the BEOL structure is the power delivery network (PDN). Backside power delivery, also referred to as a backside power delivery network (BSPDN), is a chip architecture that involves repositioning layers of the PDN from the top of the FEOL to the opposite side of the chip to free space on the front side for additional elements (e.g., more transistors). In other words, in a backside-style architecture the PDN layers are placed on the backside of the semiconductor substrate onto which the active devices have been built.

Some challenges remain, however, in effectively placing the various backside power rails and backside contacts (e.g., gate, source, and/or drain contacts) required to provide electrical continuity to the backside devices of these architectures. For example, the placement of a so-called direct backside contact (DBC) relies upon a so-called backside placeholder (also referred to as the backside contact placeholder) that is built into the structure during the FEOL. The backside placeholder can then be opened post wafer flip to allow backside access to the source/drain and/or gate. Unfortunately, accessing the backside placeholder from the backside post-wafer flip can be difficult, especially for wafer integrations having both logic and passive device regions, due in part to the silicon reservation required for passive devices. The silicon reservation for passive devices increases the depth (and aspect ratio) of the backside placeholder open and the resulting height of the DBC. The result is that a relatively larger (with respect to wafers without this integration) active region of NFET-to-active region of PFET (N2P) space is needed to accommodate the overlay variations inherit to relatively tall DBC heights.

This disclosure introduces new fabrication methods and resulting structures for DBC integration with thick silicon layers to enable passive device and tight N2P spacing. Rather than relying on a single backside placeholder pattering and growth step, additional semiconductor material (also referred to as thick silicon layer(s)) is formed over a first backside placeholder and a second backside placeholder epitaxy is grown on the first backside placeholder. The second backside placeholder epitaxy can be grown to a same thickness as a shallow trench isolation (STI) formed over the first backside placeholder. This two-step backside placeholder process, and the presence of the so-called thick silicon layer, ensures sufficient n-well height to meet passive device silicon reservation requirements, and also prevents an n-well squeeze in some device areas, such as for electrostatic discharge (ESD) diodes built from nanosheet devices.

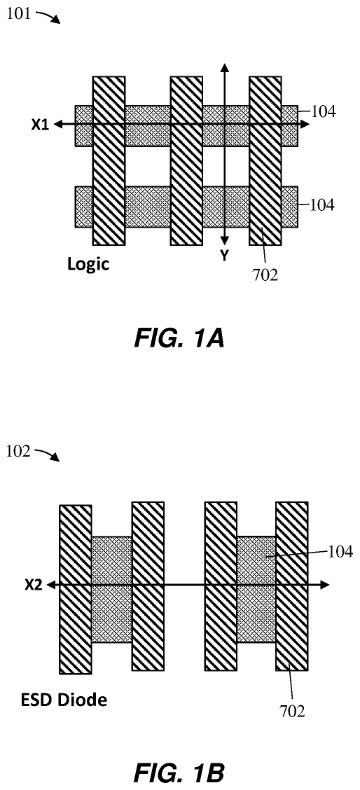

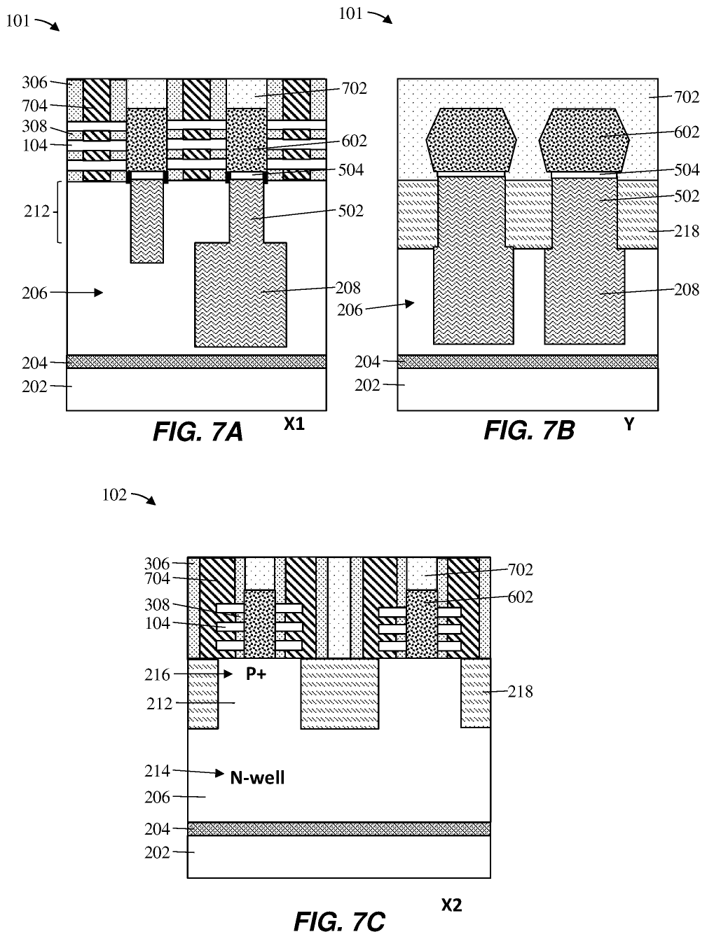

Turning now to a more detailed description of fabrication operations and resulting structures according to aspects of the disclosure, FIG. 1A depicts a top-down reference view of a first region 101 of a semiconductor wafer 100 after an initial set of fabrication operations have been applied as part of a method of fabricating a final semiconductor device according to one or more embodiments of the disclosure. FIG. 1B depicts a top-down reference view of a second region 102 of the semiconductor wafer 100 after the initial set of fabrication operations have been applied as part of a method of fabricating a final semiconductor device according to one or more embodiments of the disclosure. In some embodiments, the first region 101 is an active device region and the second region 102 is a passive device region. For example, the first region 101 can be a logic region and the second region 102 can be an ESD diode region, although other active and passive devices are within the contemplated scope of this disclosure. In some embodiments, the first region 101 and the second region 102 include one or more nanosheets 104 (collectively, nanosheet stack(s)) and respective gate(s) 704 (refer to FIGS. 7A, 7B, and 7C) formed over channel regions of the one or more nanosheets 104. The nanosheets 104, gates 704, and other elements of the semiconductor wafer 100 are discussed in greater detail with respect to the following figures.

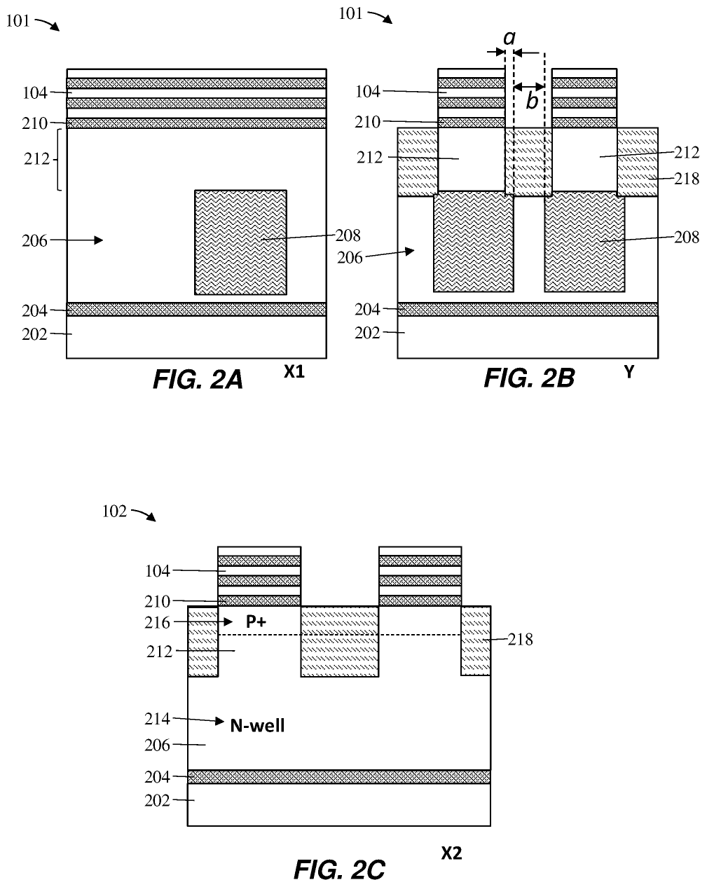

FIG. 2A depicts a cross-sectional view taken along the line X1 (across gate in channel region) in FIG. 1A. FIG. 2B depicts a cross-sectional view taken along the line Y (across channel in source/drain region) in FIG. 1A. FIG. 2C depicts a cross-sectional view taken along the line X2 (across gate in channel region) in FIG. 1B.

As shown in FIGS. 2A, 2B, and 2C, various FEOL structures have been built in the first region 101 and the second region 102 of the semiconductor wafer 100. The specific examples of the FEOL structures are illustrative only and are not meant to be particularly limited. For example, the FEOL structures depict a nanosheet-style transistor architecture. It should be understood, however, that the nanosheet-style transistor architecture of the FEOL structures is provided for ease of discussion only and that other transistor architectures (e.g., vertical tunneling transistors, planar transistors, finFETs, etc.) are included in the contemplated scope of this disclosure. Other FEOL structures can be fabricated depending on the needs of a given application, and all such configurations are within the contemplated scope of this disclosure.

In some embodiments, the semiconductor wafer 100 includes a substrate 202 (e.g., Si) having an etch stop layer 204 (e.g., a buried oxide layer or a SiGe epi layer) and an additional semiconductor layer 206 (e.g., Si) over the etch stop layer 204, although other substrate configurations and materials are within the contemplated scope of this disclosure. In some embodiments, the substrate (e.g., substrate 202/204/206) includes a silicon-on-insulator (SOI) structure and the substrate 202 is a bottommost substrate layer. The substrate 202 and/or semiconductor layer 206 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlInAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments, a first backside placeholder 208 (also referred to as a sacrificial backside placeholder) is formed in the semiconductor layer 206. In some embodiments, a backside placeholder trench (not separately indicated) is formed in the semiconductor layer 206 and the trench is filled with a sacrificial material such as, for example, silicon germanium. In some embodiments, the silicon germanium (or other sacrificial material) is epitaxially grown from exposed surfaces of the semiconductor layer 206 in the backside placeholder trench. Notably, in this sequencing, the first backside placeholder 208 can be formed prior to a subsequent nanosheet stack (that is, the nanosheets 104 and one or more sacrificial layers 210, discussed in greater detail below).

In some embodiments, a semiconductor layer 212 (also referred to as a thick silicon layer) is formed over the first backside placeholder 208. In other words, the first backside placeholder 208 can be embedded between the substrate 202/204/206 and the semiconductor layer 212. The semiconductor layer 212 can be formed (epitaxially or otherwise) of a same or different semiconductor material as the substrate 202 and/or semiconductor layer 206. For example, the semiconductor layer 212 can be an additional silicon layer epitaxially grown over the semiconductor layer 206 and the first backside placeholder 208.

In some embodiments, nanosheet stacks (not separately indicated) can be formed over the first backside placeholder 208, the substrate 202/204/206, and the semiconductor layer 212. In some embodiments, each nanosheet stack includes one or more nanosheets 104 alternating with one or more sacrificial layers 210. In some embodiments, the nanosheets 104 and the sacrificial layers 210 are epitaxially grown layers. For ease of discussion reference is made to operations performed on and to nanosheet stacks having three nanosheets (e.g., the three nanosheets 104 shown in FIGS. 2A, 2B, and 2C) alternating with three sacrificial layers (e.g., the three sacrificial layers 210 shown in FIGS. 2A, 2B, and 2C). It is understood, however, that the nanosheet stacks can include any number of nanosheets 104 alternating with a corresponding number of sacrificial layers 210. For example, the nanosheet stacks can include two nanosheets, five nanosheets, eight nanosheets, 30 nanosheets (e.g., 3D NAND), or any number of nanosheets, along with a corresponding number of sacrificial layers.

The nanosheets 104 can be made of any suitable material such as, for example, monocrystalline silicon or silicon germanium. In some embodiments, the nanosheets 104 are silicon nanosheets. In some embodiments, the nanosheets 104 have a thickness of about 4 nm to about 15 nm, for example 6 nm, although other thicknesses are within the contemplated scope of the disclosure. In some embodiments, the substrate 202 and the nanosheets 104 can be made of a same semiconductor material. In other embodiments, the substrate 202 can be made of a first semiconductor material, and the nanosheets 104 can be made of a second, different semiconductor material.

The sacrificial layers 210 can be silicon or silicon germanium layers, depending on the material of the nanosheets 104 to meet etch selectivity requirements. For example, in embodiments where the nanosheets 104 are silicon nanosheets, the sacrificial layers 210 can be silicon germanium layers. In embodiments where the nanosheets 104 are silicon germanium nanosheets, the sacrificial layers 210 can be silicon germanium layers having a germanium concentration that is greater than the germanium concentration in the nanosheets 104. For example, if the nanosheets 104 are silicon germanium having a germanium concentration of 5 percent (sometimes referred to as SiGe5), the sacrificial layers 210 can be silicon germanium layers having a germanium concentration of about 25 (SiGe25), although other germanium concentrations are within the contemplated scope of the disclosure. In some embodiments, the sacrificial layers 210 have a thickness of about 8 nm to about 15 nm, for example 10 nm, although other thicknesses are within the contemplated scope of the disclosure.

In some embodiments, a well 214 is formed in the semiconductor layer 206 and a doped region 216 is formed in the semiconductor layer 212. The well 214 and the doped region 216 can be formed, for example, using ion implantation, although other doping workflows are within the contemplated scope of this disclosure. In some embodiments, well 214 is an n-well and the doped region 216 is a P+ doped region. Such a configuration can support a variety of passive device types, such as, for example, ESD diodes. Notably, observe that the well 214 is relatively thick due to the configuration of the semiconductor layer 212 and semiconductor layer 206 (as used herein, “relatively thick” is taken with respect to wafer workflows that do not include the addition of the so-called thick semiconductor layer 212). This relatively thick n-well prevents n-well squeezing and therefore preserves current drive capability, as well as serves as a physical signature for the processing operations described herein.

In some embodiments, the nanosheets stacks are patterned and a shallow trench isolation (STI) region 218 is formed in the semiconductor layer 206. The STI region 218 can be made of any suitable dielectric material, such as, for example, silicon oxide, silicon nitride, silicon carbide, hydrogenated silicon carbonitrides, silicon oxynitrides, and silicon borocarbonitrides, although other dielectrics are within the contemplated scope of the disclosure. In some embodiments, the STI region 218 is formed by exposing a surface of the semiconductor layer 212 and recessing through a portion of the semiconductor layer 206. Observe that a frontside processing window for the backside contact placeholder is made relatively easier due to the addition of the so-called thick semiconductor layer 212. The result is a relatively short overhang a, allowing the backside placeholder-to-backside placeholder spacing b to be relaxed (in other words, the spacing b can be made as wide as possible). The relatively wider placeholder-to-backside placeholder spacing b helps to prevent placeholder shorts and relaxes processing window alignment constraints. Moreover, the relatively short overhang a and relatively wider placeholder-to-backside placeholder spacing b are observable in the final device, and serve as a physical signature for the processing operations described herein.

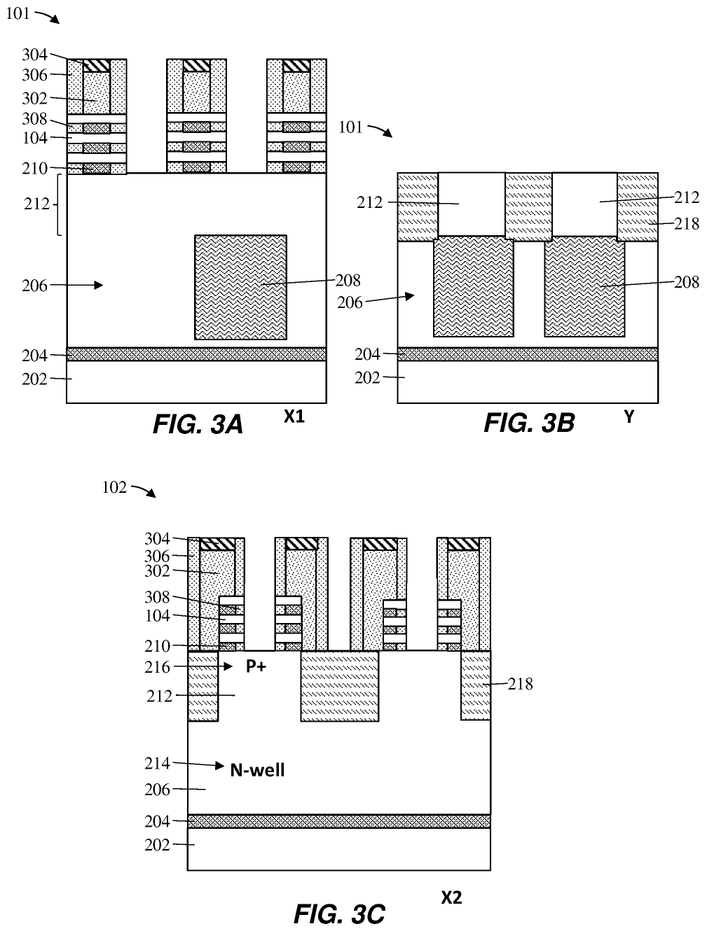

FIG. 3A depicts a cross-sectional view taken along line X1 after additional process operations. FIG. 3B depicts a cross-sectional view taken along line Y after additional process operations. FIG. 3C depicts a cross-sectional view taken along line X2 after additional process operations.

In some embodiments, a sacrificial gate 302 (sometimes referred to as a dummy gate) is formed over channel regions of the nanosheets 104. As used herein, a “channel region” refers to the portion of a nanosheet over which a gate is formed, and through which current passes from source to drain in the final device (after gate metallization). The sacrificial gate 302 can be made of any suitable material, such as, for example, amorphous silicon or polysilicon. Any known method for patterning a sacrificial gate can be used, such as, for example, a wet etch, a dry etch, or a combination of sequential wet and/or dry etches. In some embodiments, a gate hard mask 304 is formed over the sacrificial gate 302. The gate hard mask 304 can include any suitable hard mask material, such as, for example, silicon nitride.

In some embodiments, dielectric material is conformally deposited over the semiconductor wafer 100 and patterned to define gate spacers 306. The dielectric material can include, for example, silicon oxide, silicon nitride, silicon carbide, hydrogenated silicon carbonitrides, silicon oxynitrides, and silicon borocarbonitrides, although other dielectrics are within the contemplated scope of the disclosure.

In some embodiments, portions of the nanosheets 104 and sacrificial layers 210 can be removed (sometimes referred to as a stack recess or fin recess, depending on the transistor architecture) to expose a surface of the semiconductor layer 212. The nanosheets 104 and sacrificial layers 210 can be patterned using, for example, a wet etch, a dry etch, or a combination of wet and/or dry etches. In some embodiments, the nanosheets 104 and sacrificial layers 210 are patterned using a RIE. In some embodiments, the nanosheets 104 and sacrificial layers 210 are patterned selective to the gate spacers 306.

In some embodiments, exposed sidewalls of the sacrificial layers 210 can be recessed and inner spacers 308 can be formed on the recessed sidewalls of the sacrificial layers 210. For example, sidewalls of the sacrificial layers 210 can be recessed to form cavities (not shown) and the inner spacers 308 can be formed by filling these cavities with dielectric material. In some embodiments, portions of the inner spacers 308 that extend beyond sidewalls of the nanosheets 104 are removed, using, for example, an isotropic etching process. In this manner, sidewalls of the inner spacers 308 can be coplanar to sidewalls of the nanosheets 104. In some embodiments, the inner spacers 308 are formed using a chemical vapor deposition (CVD), plasma-enhanced CVD (PECVD), atomic layer deposition (ALD), physical vapor deposition (PVD), chemical solution deposition, or other like processes in combination with a wet or dry etch process. The inner spacers 308 can be made of any suitable material, such as, for example, a low-k dielectric, a nitride, silicon nitride, silicon dioxide, SiON, SiC, SiOCN, or SiBCN.

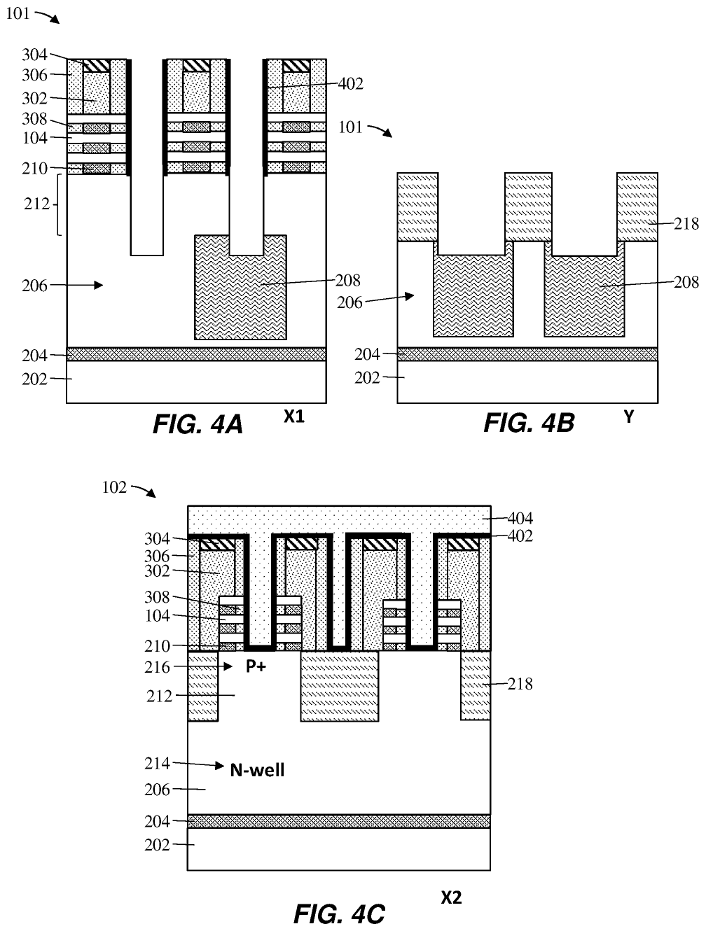

FIG. 4A depicts a cross-sectional view taken along line X1 after additional process operations. FIG. 4B depicts a cross-sectional view taken along line Y after additional process operations. FIG. 4C depicts a cross-sectional view taken along line X2 after additional process operations.

In some embodiments, a protective liner 402 is formed over the semiconductor wafer 100. In some embodiments, the protective liner 402 is conformally deposited over the semiconductor wafer 100. In some embodiments, the protective liner 402 has a thickness of about 2 nm to about 6 nm, although other thicknesses are within the contemplated scope of the disclosure. In some embodiments, the protective liner 402 is formed using CVD, PECVD, ultrahigh vacuum CVD (UHVCVD), rapid thermal CVD (RTCVD), metalorganic CVD (MOCVD), low-pressure CVD (LPCVD), limited reaction processing CVD (LRPCVD), ALD, PVD, chemical solution deposition, molecular beam epitaxy (MBE), or other like process in combination with a wet or dry etch process. The protective liner 402 can be made of any suitable dielectric material, such as, for example, silicon oxide, silicon nitride, silicon carbide, hydrogenated silicon carbonitrides (SiC(N, H)), silicon oxynitrides (SiC(N, O, H)), and silicon borocarbonitrides (SiBCN), although other dielectrics are within the contemplated scope of the disclosure.

In some embodiments, a patterning film stack 404 can be formed over the second region 102 of the semiconductor wafer 100. The patterning film stack 404 can be a bi-layer stack, a tri-layer stack, or a multilayer stack including an organic planarization layer (OPL) (not separately indicated). The patterning film stack 404 can also include an antireflective coating and a topmost photoresist layer (these additional possible layers not separately shown). Patterning layer stacks typically include OPLs because high resolution photoresists themselves often do not provide enough etch resistance for pattern transfer. OPLs are used as etch masks for pattern transfers into inorganic substrates, to fill pre-existing features, and to planarize the substrate to allow for larger patterning process windows.

The OPL can be formed over a surface of the semiconductor wafer 100 using any suitable process. In some embodiments, the OPL can be applied using, for example, spin coating technology. In some embodiments, the OPL can include a photo-sensitive organic polymer having a light-sensitive material that, when exposed to electromagnetic (EM) radiation, is chemically altered and thus configured to be removed using a developing solvent. For example, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). More generally, for example, the OPL can include any organic polymer and a photo-active compound having a molecular structure that can attach to the molecular structure of the organic polymer. In some embodiments, the OPL material is selected to be compatible with the overlying antireflective coating (if present), the overlying photoresist (if present), and the lithographic wavelength employed (e.g., ArF, KrF, etc.).

The antireflective coating can be made of any suitable antireflective material, such as, for example, a low temperature oxide (LTO), SiARC, TiARC, or SiON. The antireflective coating can be deposited using, for example, a spin-on process. The photoresist can include any suitable photoresist material, such as, for example, 248 nm resists, 193 nm resists, 157 nm resists, or EUV (extreme ultraviolet) resists. In some embodiments, the photoresist can be made of a light sensitive polymer, and can be deposited using any suitable resist process, such as spin-on coating.

In some embodiments, exposed portions of the semiconductor layer 212 (e.g., those portions in the first region 101 not covered by the pattering film stack 404) can be recessed to expose the first backside placeholder 208. In some embodiments, the first backside placeholder 208 is also recessed (as shown). These processes can be referred to as backside contact patterning.

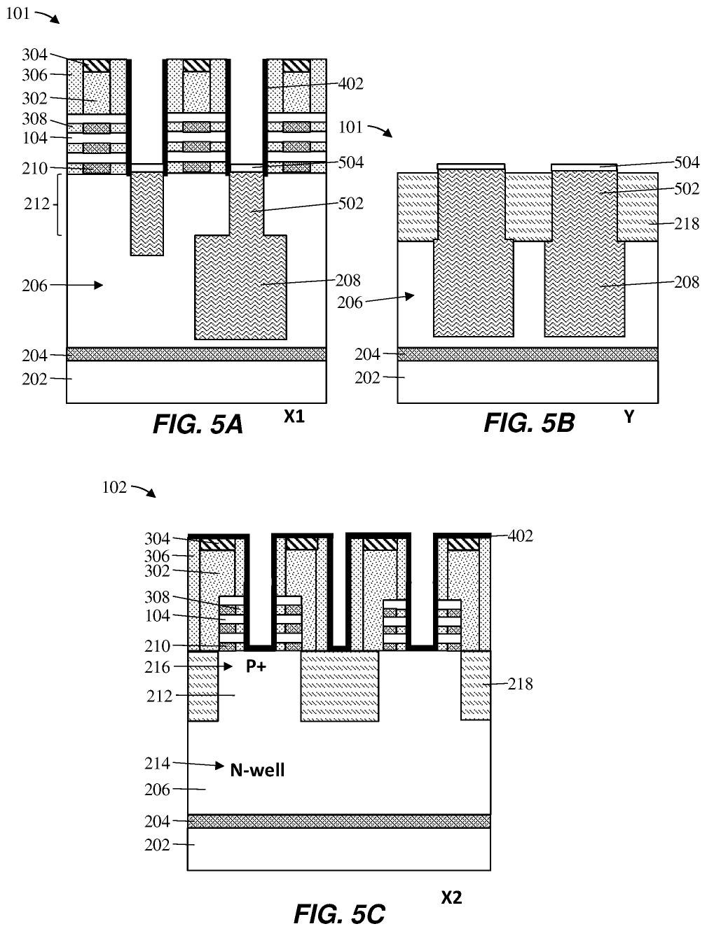

FIG. 5A depicts a cross-sectional view taken along line X1 after additional process operations. FIG. 5B depicts a cross-sectional view taken along line Y after additional process operations. FIG. 5C depicts a cross-sectional view taken along line X2 after additional process operations.

In some embodiments, a second backside placeholder 502 is formed on the first backside placeholder 208. The second backside placeholder 502 can be made by epitaxially growing additional sacrificial material over the first backside placeholder 208. In some embodiments, the second backside placeholder 502 is made of the same material as the first backside placeholder 208 and serves to effectively increase the volume of the first backside placeholder 208. In some embodiments, a relatively thin silicon cap 504 can be formed over the second backside placeholder 502.

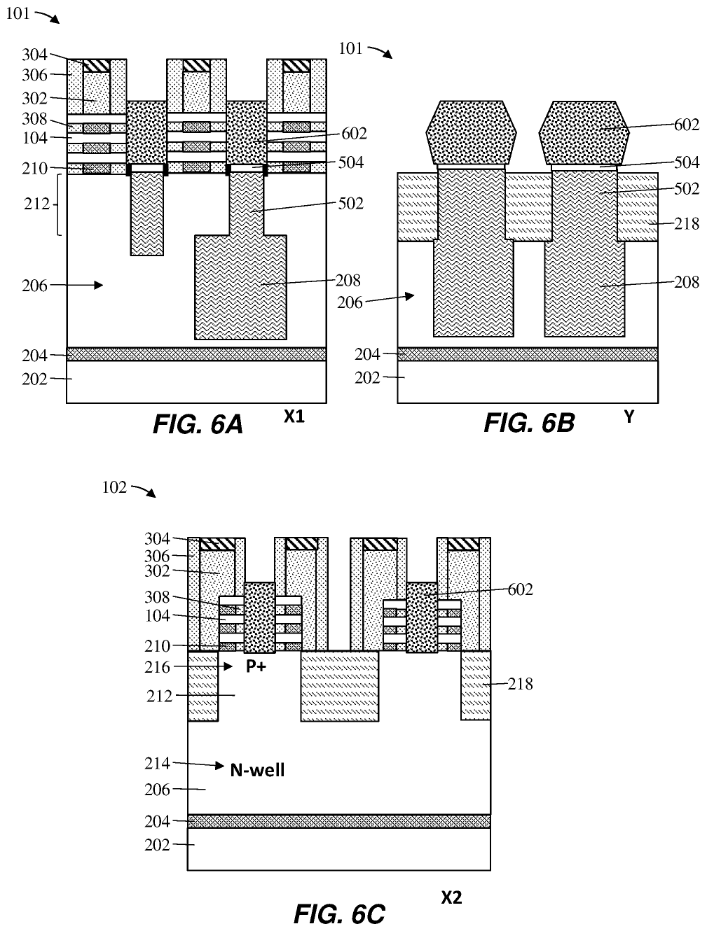

FIG. 6A depicts a cross-sectional view taken along line X1 after additional process operations. FIG. 6B depicts a cross-sectional view taken along line Y after additional process operations. FIG. 6C depicts a cross-sectional view taken along line X2 after additional process operations.

In some embodiments, the protective liner 402 is removed and source/drain regions 602 are formed over the second backside placeholder 502 (refer to FIGS. 6A and 6B) and/or semiconductor layer 212 (refer to FIG. 6C). The source/drain regions 602 can be epitaxially grown using, for example, vapor-phase epitaxy (VPE), molecular beam epitaxy (MBE), liquid-phase epitaxy (LPE), or other suitable processes. The source/drain regions 602 can be semiconductor materials epitaxially grown from gaseous or liquid precursors. In some embodiments of the disclosure, the gas source for the epitaxial deposition of semiconductor material includes a silicon containing gas source, a germanium containing gas source, or a combination thereof. For example, a silicon layer can be epitaxially deposited (or grown) from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. A germanium layer can be epitaxially deposited from a germanium gas source that is selected from the group consisting of germane, digermane, halogermane, dichlorogermane, trichlorogermane, tetrachlorogermane and combinations thereof. A silicon germanium alloy layer can be epitaxially formed utilizing a combination of such gas sources. Carrier gases like hydrogen, nitrogen, helium and argon can be used. In some embodiments of the disclosure, the epitaxial semiconductor materials include carbon doped silicon (Si:C). This Si:C layer can be grown in the same chamber used for other epitaxy steps or in a dedicated Si:C epitaxy chamber. The Si:C can include carbon in the range of about 0.2 percent to about 3.0 percent.

Epitaxially grown silicon and silicon germanium can be doped by adding n-type dopants (e.g., P or As) or p-type dopants (e.g., Ga, B, BF₂, or Al) as desired. In some embodiments, a portion of the source/drain regions 602 are of a first doping type (e.g., n-type) and a second portion of the source/drain regions 602 are of a second doping type (e.g., p-type), as desired. In some embodiments, the source/drain regions 602 are of the same doping type. The source/drain regions 602 can be epitaxially formed and doped by a variety of methods, such as, for example, in-situ doped epitaxy (doped during deposition), doped following the epitaxy, or by implantation and plasma doping. The dopant concentration in the doped regions can range from 1×10¹⁹ cm⁻³ to 2×10²¹ cm⁻³, or between 1×10²⁰ cm⁻³ and 1×10²¹ cm⁻³.

FIG. 7A depicts a cross-sectional view taken along line X1 after additional process operations. FIG. 7B depicts a cross-sectional view taken along line Y after additional process operations. FIG. 7C depicts a cross-sectional view taken along line X2 after additional process operations.

In some embodiments, an interlayer dielectric (ILD) 702 is formed over the source/drain regions 602. The ILD 702 can be made of any suitable dielectric material, such as, for example, oxides, a low-k dielectric, nitrides, silicon nitride, silicon oxide, SiON, SiC, SiOCN, and SiBCN. In some embodiments, the ILD 702 is deposited over the semiconductor wafer 100 and the semiconductor wafer 100 is then planarized using, for example, CMP.

In some embodiments, the gate hard mask 304, the sacrificial gate 302, and the sacrificial layers 210 can be removed to release the nanosheets 104. The gate hard mask 304, the sacrificial gate 302, and the sacrificial layers 210 can be removed selective to the nanosheets 104. For example, when the nanosheets 104 are formed of silicon and the sacrificial layers 210 are formed of silicon germanium, hydrogen chloride (HCl) gas, or an aqueous solution containing a mix of ammonia and hydrogen peroxide can be utilized to remove silicon germanium selective to silicon. In another example, when the nanosheets 104 are formed of silicon germanium and the sacrificial layers 210 are formed of silicon, aqueous hydroxide chemistry, including ammonium hydroxide and potassium hydroxide, can be utilized to remove silicon selective to silicon germanium.

In some embodiments, the removed sacrificial gate 302 can be replaced with a conductive gate 704. The conductive gate 704 can be a high-k metal gate (HKMG) formed over channel regions of the nanosheets 104 using, for example, known replacement metal gate (RMG) processes, or so-called gate-last processes. In some embodiments, the conductive gate 704 can include a gate dielectric and a work function metal stack (not separately depicted). In some embodiments, the gate dielectric is a high-k dielectric film formed on a surface (sidewall) of the nanosheets 104. The high-k dielectric film can be made of, for example, silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum. In some embodiments, the high-k dielectric film can have a thickness of about 0.5 nm to about 4 nm.

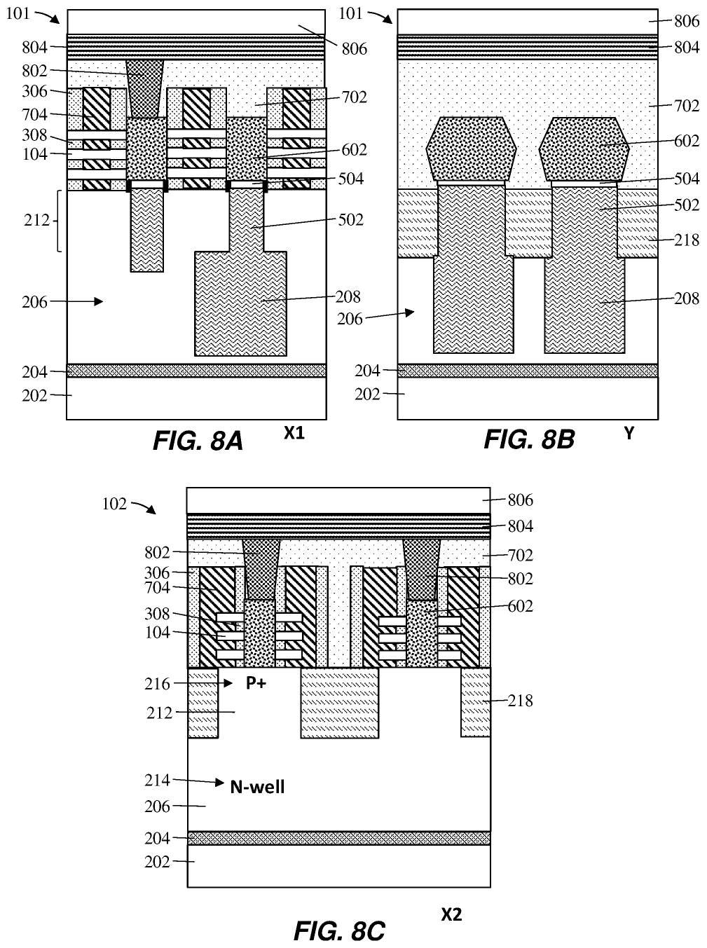

FIG. 8A depicts a cross-sectional view taken along line X1 after additional process operations. FIG. 8B depicts a cross-sectional view taken along line Y after additional process operations. FIG. 8C depicts a cross-sectional view taken along line X2 after additional process operations.

In some embodiments, one or more frontside source/drain contact(s) 802 are formed over the source/drain regions 602. This process can be referred to as a MOL contact module, or simply, as the MOL. The frontside source/drain contact(s) 802 can be formed from conductive materials that include copper or a non-copper metal (e.g., tungsten, titanium, tantalum, ruthenium, zirconium, cobalt, aluminum, platinum), alloys thereof, conducting metallic compound material (e.g., tantalum nitride, titanium nitride, tantalum carbide, titanium carbide, titanium aluminum carbide, tungsten silicide, tungsten nitride, cobalt silicide, nickel silicide, titanium silicide), conductive carbon, or any suitable combination of these materials.

In some embodiments, a frontside interconnect 804 (which itself can include any number of levels of vias and lines) can be formed over the semiconductor wafer 100. The frontside interconnect 804 shown is merely illustrative and the semiconductor wafer 100 can include any number of BEOL structures (e.g., additional interconnect layers, vias, lines, etc.) and all such configurations are within the contemplated scope of this disclosure.

In some embodiments, a carrier wafer 806 (also referred to as a bonding carrier wafer) is formed over the frontside interconnect 804. The carrier wafer 806 can be made of a same or different material as the substrate 202/204/206, such as silicon and/or a wafer handling material.

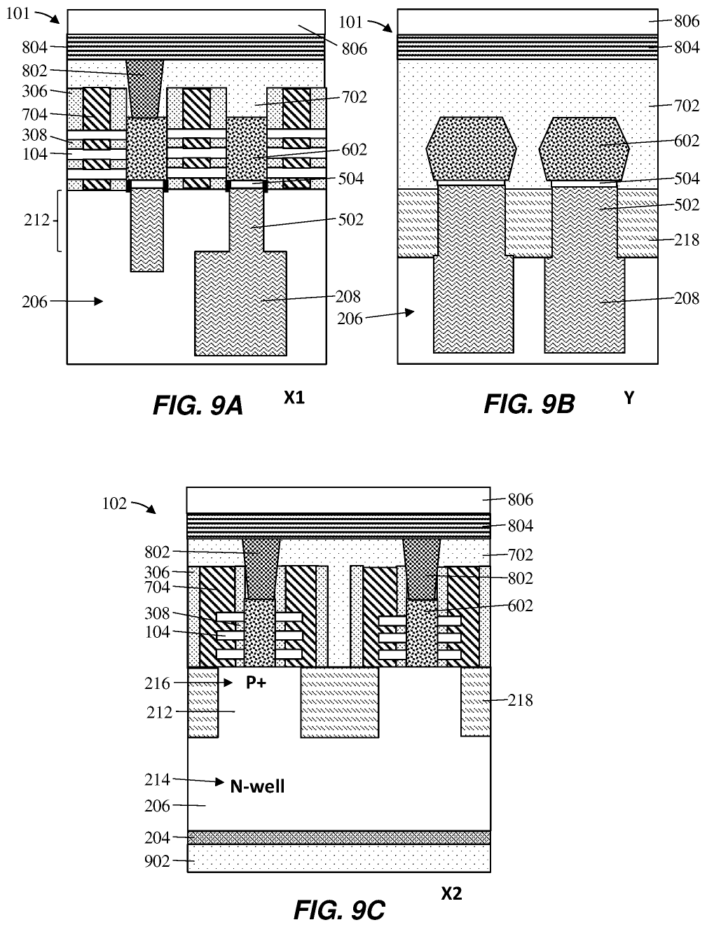

FIG. 9A depicts a cross-sectional view taken along line X1 after additional process operations. FIG. 9B depicts a cross-sectional view taken along line Y after additional process operations. FIG. 9C depicts a cross-sectional view taken along line X2 after additional process operations.

In some embodiments, the semiconductor wafer 100 is flipped and the substrate 202 is removed post-wafer flip. In some embodiments, removal of the substrate 202 lands (or stops) on the etch stop layer 204. For example, the substrate 202 can be removed by grinding and/or chemical-mechanical planarization (CMP), followed by dry etch and wet etch processes to remove substrate 202 (e.g., silicon), stopping on the etch stop layer 204. Note that the orientation of the semiconductor wafer 100 shown in FIGS. 9A, 9B, and 9C remains fixed for ease of discussion. In some embodiments, the etch stop layer 204 is removed after stripping off the substrate 202 to expose portions of the semiconductor layer 206.

In some embodiments, a patterning film stack 902 (e.g., an OPL) is formed over the etch stop layer 204 in the second region 102 of the semiconductor wafer 100 (refer to FIG. 9C). In this manner, the etch stop layer 204 can be preserved in the second region 102 when the etch stop layer 204 is removed from the first region 101.

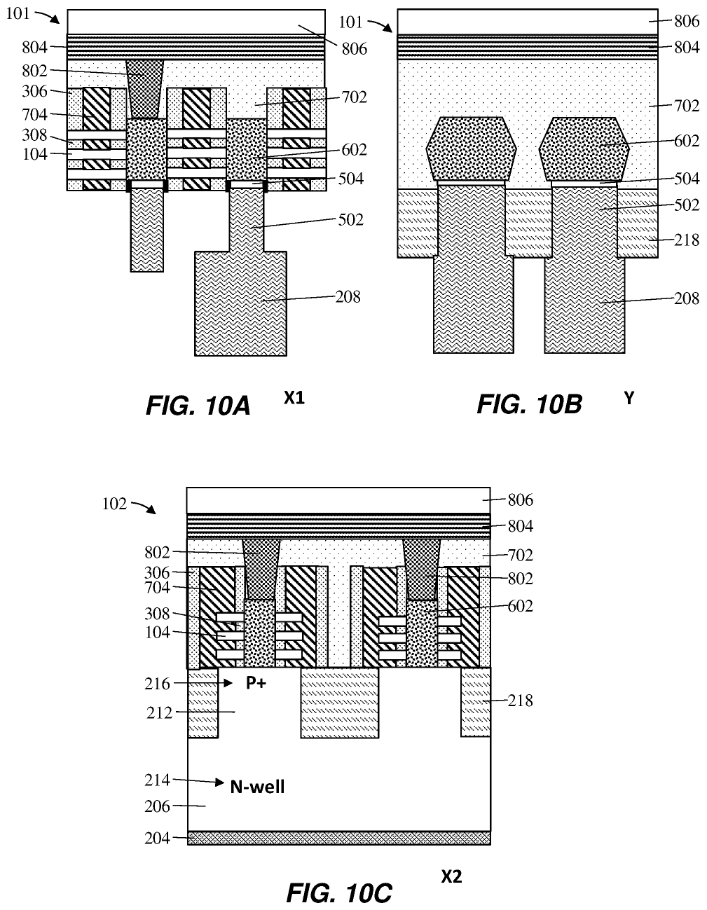

FIG. 10A depicts a cross-sectional view taken along line X1 after additional process operations. FIG. 10B depicts a cross-sectional view taken along line Y after additional process operations. FIG. 10C depicts a cross-sectional view taken along line X2 after additional process operations.

In some embodiments, the semiconductor layer 206 and semiconductor layer 212 are removed after removing the etch stop layer 204 (refer to FIGS. 10A and 10B). In some embodiments, the semiconductor layer 206 and semiconductor layer 212 are removed selective to the first backside placeholder 208, the second backside placeholder 502, and/or the STI region 218.

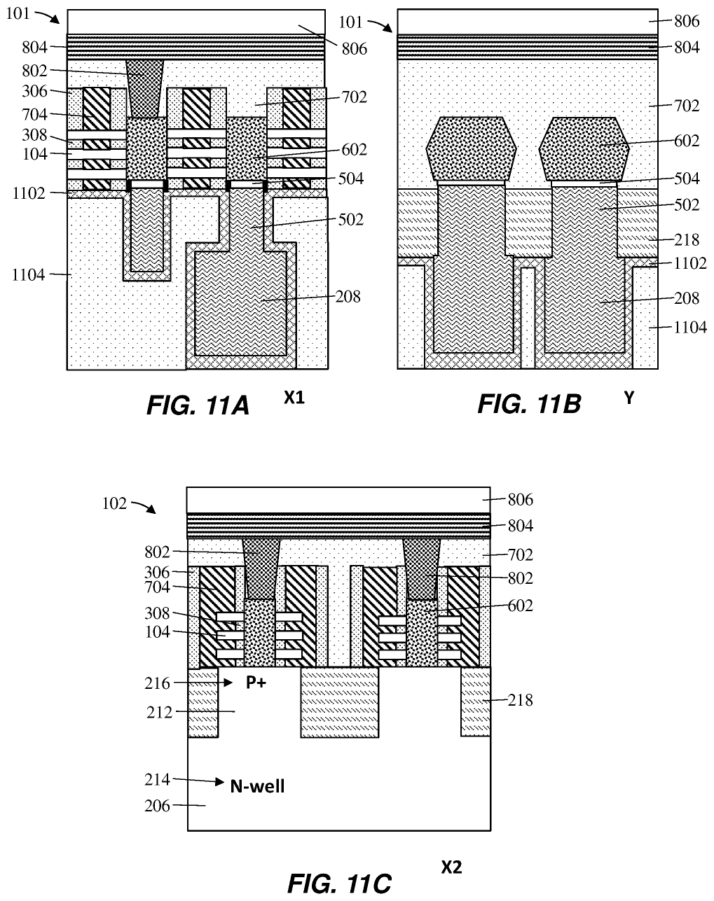

FIG. 11A depicts a cross-sectional view taken along line X1 after additional process operations. FIG. 11B depicts a cross-sectional view taken along line Y after additional process operations. FIG. 11C depicts a cross-sectional view taken along line X2 after additional process operations.

In some embodiments, a backside contact dielectric liner 1102 is formed over the first backside placeholder 208 and the second backside placeholder 502. In some embodiments, the backside contact dielectric liner 1102 is conformally deposited over the first backside placeholder 208 and the second backside placeholder 502. In this manner, the backside contact dielectric liner 1102 will continuously wrap-around the first backside placeholder 208 and the second backside placeholder 502. In some embodiments, the backside contact dielectric liner 1102 has a thickness of about 10 nm to about 60 nm, although other thicknesses are within the contemplated scope of the disclosure. The backside contact dielectric liner 1102 can be made of any suitable dielectric material, such as, for example, silicon oxide, silicon nitride, silicon carbide, hydrogenated silicon carbonitrides (SiC(N, H)), silicon oxynitrides (SiC(N, O, H)), and silicon borocarbonitrides (SiBCN), although other dielectrics are within the contemplated scope of the disclosure.

In some embodiments, a backside interlayer dielectric (BILD) 1104 is formed over the semiconductor wafer 100. The BILD 1104 (also referred to as a FOX oxide) can be made from any suitable dielectric material, such as, for example, a low-k dielectric, a nitride, silicon nitride, silicon oxide, SiON, SiC, SiOCN, SiBCN, etc. In some embodiments, the BILD 1104 is made of a material selected to allow for etch selectivity with respect to the first backside placeholder 208, the second backside placeholder 502, and/or the backside contact dielectric liner 1102. In some embodiments, the BILD 1104 is deposited over the semiconductor wafer 100 and the semiconductor wafer 100 is then planarized using, for example, CMP.

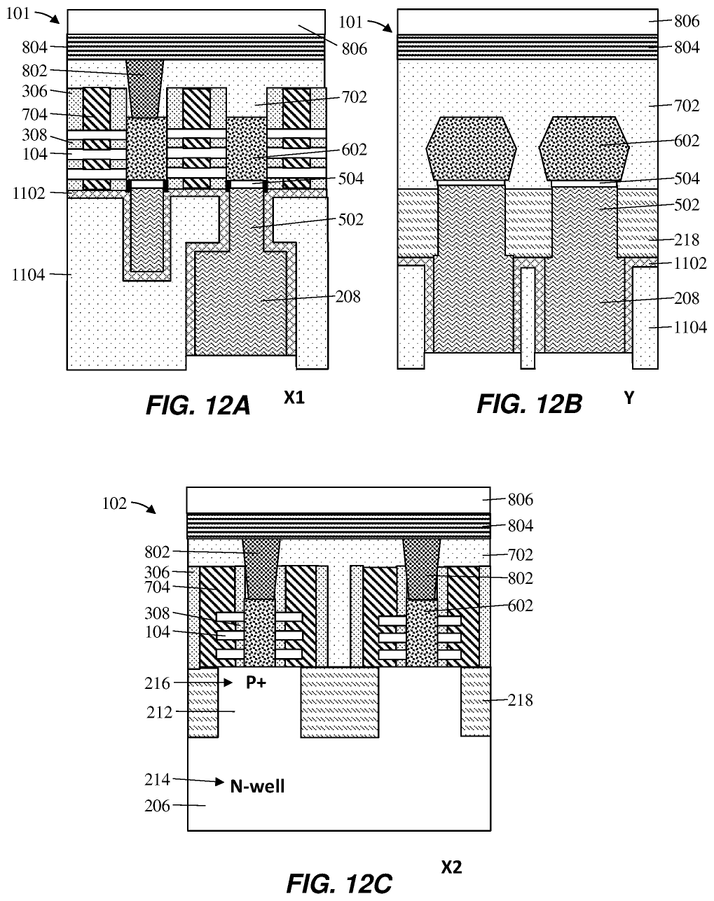

FIG. 12A depicts a cross-sectional view taken along line X1 after additional process operations. FIG. 12B depicts a cross-sectional view taken along line Y after additional process operations. FIG. 12C depicts a cross-sectional view taken along line X2 after additional process operations.

In some embodiments, a portion of the backside contact dielectric liner 1102 is removed to expose a surface of the first backside placeholder 208. The backside contact dielectric liner 1102 can be patterned using, for example, a wet etch, a dry etch, or a combination of wet and/or dry etches.

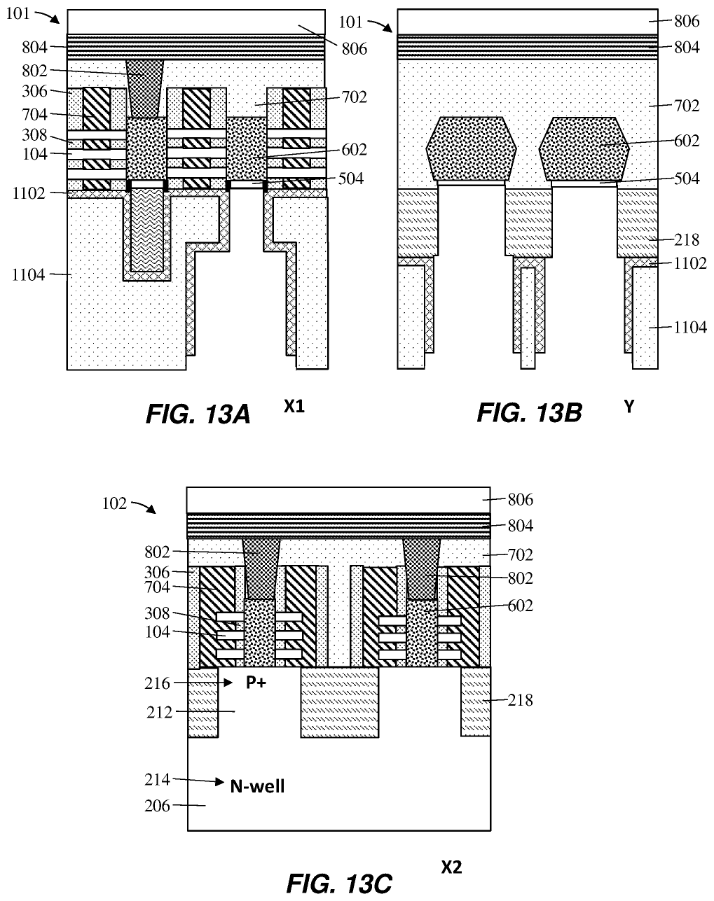

FIG. 13A depicts a cross-sectional view taken along line X1 after additional process operations. FIG. 13B depicts a cross-sectional view taken along line Y after additional process operations. FIG. 13C depicts a cross-sectional view taken along line X2 after additional process operations.

In some embodiments, the first backside placeholder 208 and the second backside placeholder 502 are removed to expose a surface of the silicon cap 504. In some embodiments, the first backside placeholder 208 and the second backside placeholder 502 are removed selective to the backside contact dielectric liner 1102, the STI region 218, and/or the silicon cap 504.

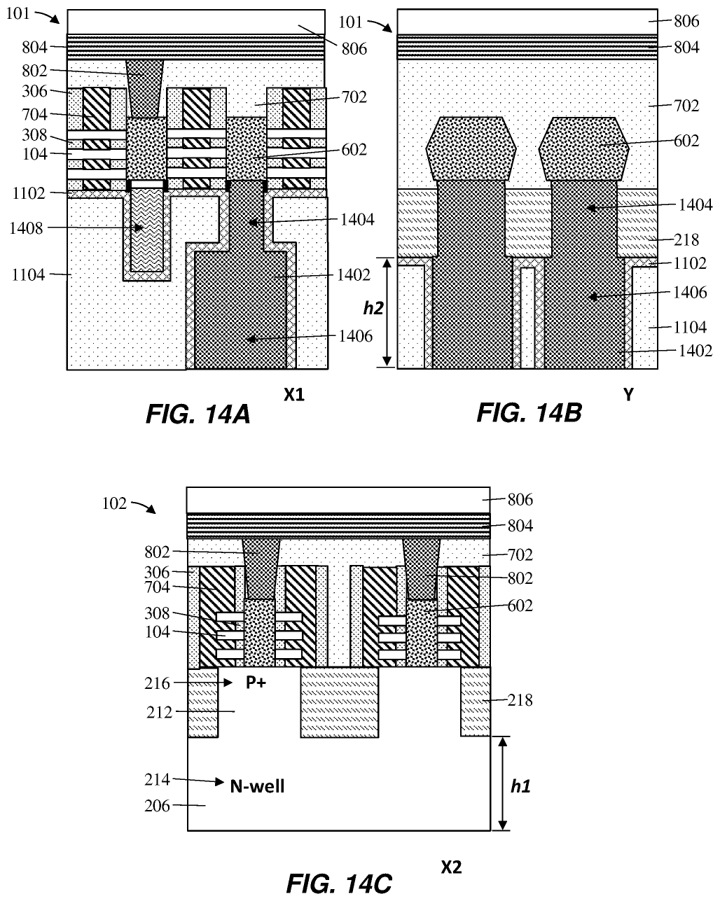

FIG. 14A depicts a cross-sectional view taken along line X1 after additional process operations. FIG. 14B depicts a cross-sectional view taken along line Y after additional process operations. FIG. 14C depicts a cross-sectional view taken along line X2 after additional process operations.

In some embodiments, the first backside placeholder 208 and the second backside placeholder 502 are replaced with conductive material (e.g., metals, doped semiconductors, etc.) to define a backside contact 1402 (also referred to as a backside S/D contact). This process can be referred to as the backside S/D contact metallization. In some embodiments, the silicon cap 504 is removed prior to backside S/D contact metallization (as shown). The silicon cap 504 can be removed using, for example, a silicon etch.

Observe that the backside contact 1402 includes an upper portion 1404 (that portion which replaced the second backside placeholder 502 and/or the silicon cap 504) and a lower portion 1406 (that portion which replaced the first backside placeholder 208), each surrounded conformally by the backside contact dielectric liner 1102. Observe further that the lower portion 1406 has a wider width (a larger critical dimension) than the upper portion 1404. Also, the backside contact dielectric liner 1102 extends under and in direct contact with portions of the conductive gate 704. In addition, the backside contact dielectric liner 1102 also conformally wraps around an unremoved portion 1408 (also referred to as a residual backside contact placeholder) of the second backside placeholder 502 that remains for all portions of the first region 101 where contact is made via the frontside of the wafer rather than the backside of the wafer (refer to FIG. 14A). Finally, in the passive device regions (e.g., in the second region 102), a height h1 of the remaining silicon layer (that is, the semiconductor layer 206) under the STI region 218 is the same as the height h2 of the lower portion 1406 of the backside contact 1402. These features serve as additional physical signatures for the processing operations described herein.

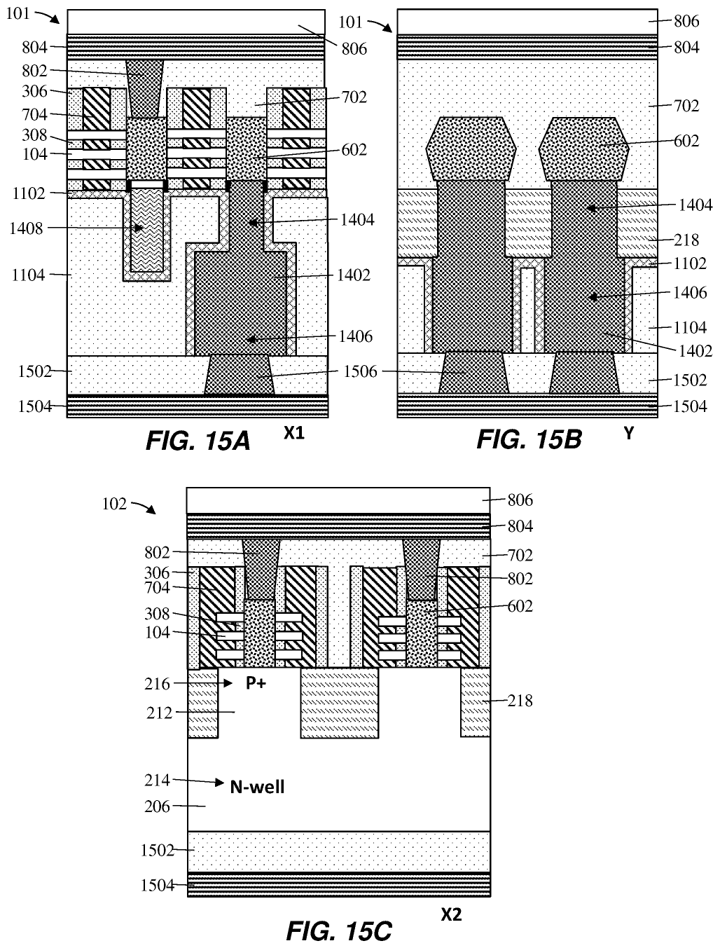

FIG. 15A depicts a cross-sectional view taken along line X1 after additional process operations. FIG. 15B depicts a cross-sectional view taken along line Y after additional process operations. FIG. 15C depicts a cross-sectional view taken along line X2 after additional process operations.

In some embodiments, additional BILD 1502 and a backside interconnect 1504 are formed over the semiconductor wafer 100. The backside interconnect 1504 can include, for example, a backside power delivery network (BSPDN), although other interconnect structures are within the contemplated scope of this disclosure. The backside interconnect 1504 can include any number of conductive/metal layers, lines, and vias (e.g., one or more backside vias 1506), and can be formed in a similar manner as the frontside interconnect 804 discussed previously, except that the backside interconnect 1504 is formed on an opposite side of the semiconductor wafer 100. Additional backside layers, structures, and dielectrics (omitted for clarity) can be formed before or after the backside interconnect 1504.

After backside processing is complete, the semiconductor wafer 100 can be finalized using known processes (e.g., additional BEOL, far back end of line (FBEOL), and packaging processes used to define a final device, including the incorporation of additional frontside and/or backside metallization layers).

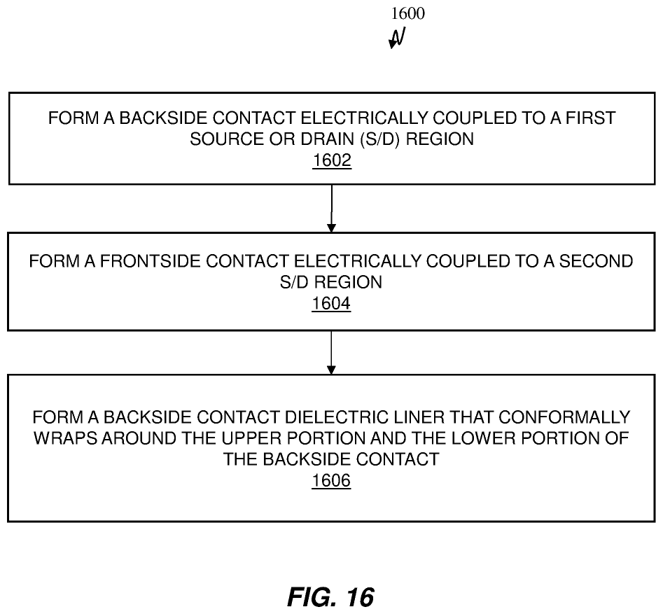

FIG. 16 depicts a flow diagram illustrating a method 1600 for providing direct backside contact integrations with thick silicon layers to enable passive device and tight active region of NFET-to-active region of PFET (N2P) spacing according to one or more embodiments. The method 1600 is described in reference to FIGS. 1A-15C and may include additional blocks not depicted in FIG. 16. Although depicted in a particular order, the blocks depicted in FIG. 16 can be rearranged, subdivided, and/or combined.

As shown at block 1602, the method includes forming a backside contact electrically coupled to a first S/D region. In some embodiments, the backside contact includes an upper portion and a lower portion. In some embodiments, the lower portion has a larger critical dimension (e.g., width) than the upper portion.

As shown at block 1602, the method includes forming a frontside contact electrically coupled to a second S/D region.

As shown at block 1604, the method includes forming a backside contact dielectric liner that conformally wraps around the upper portion and the lower portion of the backside contact.

In some embodiments, the backside contact dielectric liner extends under and in direct contact with portions of a conductive gate. In some embodiments, the conductive gate is electrically coupled to the first S/D region and second S/D region.

In some embodiments, the backside contact dielectric liner conformally wraps around a residual backside contact placeholder. In some embodiments, the residual backside contact placeholder is in direct contact with a silicon cap. In some embodiments, the silicon cap is in direct contact with the second S/D region.

In some embodiments, the method includes forming a passive device region having a silicon layer under a shallow trench isolation region. In some embodiments, a height of the silicon layer under the shallow trench isolation region in the passive device region and a height of the lower portion of the backside contact are the same.

In some embodiments, the method includes forming a first backside placeholder having a first critical dimension and forming a second backside placeholder on the first backside placeholder. In some embodiments, the second backside placeholder has a second critical dimension (e.g., width) less than the first critical dimension.

In some embodiments, a semiconductor layer is formed over and in direct contact with the first backside placeholder. In some embodiments, the semiconductor layer is recessed to expose a surface of the first backside placeholder. In some embodiments, the recessed portions of the semiconductor layer are replaced with sacrificial material to define the second backside placeholder.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the disclosure, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a backside contact electrically coupled to a first source or drain (S/D) region, the backside contact comprising an upper portion and a lower portion, the lower portion having a larger critical dimension than the upper portion;
forming a frontside contact electrically coupled to a second S/D region; and
forming a backside contact dielectric liner that conformally wraps around the upper portion and the lower portion of the backside contact.

2. The method of claim 1, wherein the backside contact dielectric liner extends under and in direct contact with portions of a conductive gate.

3. The method of claim 2, wherein the conductive gate is electrically coupled to the first S/D region and to the second S/D region.

4. The method of claim 1, wherein the backside contact dielectric liner conformally wraps around a residual backside contact placeholder.

5. The method of claim 4, wherein the residual backside contact placeholder is in direct contact with a silicon cap.

6. The method of claim 5, wherein the silicon cap is in direct contact with the second S/D region.

7. The method of claim 1, further comprising forming a passive device region having a silicon layer under a shallow trench isolation region.

8. The method of claim 7, wherein a height of the silicon layer under the shallow trench isolation region in the passive device region and a height of the lower portion of the backside contact are the same.

9. The method of claim 1, wherein forming the backside contact comprises:
forming a first backside placeholder having a first critical dimension; and
forming a second backside placeholder on the first backside placeholder, the second backside placeholder having a second critical dimension less than the first critical dimension.

10. The method of claim 9, wherein forming the backside contact further comprises forming a semiconductor layer over and in direct contact with the first backside placeholder.

11. The method of claim 10, wherein forming the backside contact further comprises recessing portions of the semiconductor layer to expose a surface of the first backside placeholder.

12. The method of claim 11, wherein forming the backside contact further comprises replacing the recessed portions of the semiconductor layer with sacrificial material to define the second backside placeholder.

13. A semiconductor device comprising:
a backside contact electrically coupled to a first source or drain (S/D) region, the backside contact comprising an upper portion and a lower portion, the lower portion having a larger critical dimension than the upper portion;
a frontside contact electrically coupled to a second S/D region; and
a backside contact dielectric liner conformally wrapping around the upper portion and the lower portion of the backside contact.

14. The semiconductor device of claim 13, wherein the backside contact dielectric liner extends under and in direct contact with portions of a conductive gate.

15. The semiconductor device of claim 14, wherein the conductive gate is electrically coupled to the first S/D region and to the second S/D region.

16. The semiconductor device of claim 13, wherein the backside contact dielectric liner conformally wraps around a residual backside contact placeholder.

17. The semiconductor device of claim 16, wherein the residual backside contact placeholder is in direct contact with a silicon cap.

18. The semiconductor device of claim 17, wherein the silicon cap is in direct contact with the second S/D region.

19. The semiconductor device of claim 13, further comprising a passive device region having a silicon layer under a shallow trench isolation region.

20. The semiconductor device of claim 19, wherein a height of the silicon layer under the shallow trench isolation region in the passive device region and a height of the lower portion of the backside contact are the same.
